(19) United States
(12) Patent Application Publication
(10) Pub. No.: US 2013/0286552 A1
(43) Pub. Date: Oct. 31, 2013

(54) PROTECTIVE CASE OF MOBILE ELECTRONIC DEVICE

(71) Applicant: CHI-LIANG WEI, New Taipei City (TW)

(72) Inventor: CHI-LIANG WEI, New Taipei City (TW)

(21) Appl. No.: 13/456,220

(22) Filed: Apr. 26, 2012

(51) Int. Cl. H05K 5/02

(52) U.S. Cl. 361/679.01

(57) ABSTRACT

The invention is directed to a protective case of a movable electronic device. The protective case comprises a protective device enclosing the movable electronic device, wherein the protective device comprises a side frame, a top cover and a bottom cover, wherein the movable electronic device comprises a smart phone or a tablet personal computer, wherein the protective device comprises a fluorescent portion and a rubber quakeproof buffer portion at an inner side thereof. The fluorescent portion is easily recognized at night, and a quakeproof effect and an eye-catching effect at night can be achieved.

### BACKGROUND OF THE DISCLOSURE

a) Field of the Disclosure

The invention relates to a protective case of an electronic device, and more particularly, to a protective case of a mobile electronic device, wherein the protective case is quakeproof and eye-catching at night.

b) Brief Description of the Related Art

Smartphones or tablet personal computers are widely favored by consumers and frequently used. The smartphones or tablet personal computers would be worn away or damaged due to being unconsciously struck. Various protective cases have been developed to protect backs and sides thereof, but have no quakeproof effects. It is difficult to find them when placed in a dark room.

### SUMMARY OF THE DISCLOSURE

In order to improve the above disadvantages, the inventor collected related information, had evaluation and consideration in many ways based on long experience on this field and straight did tests and modification, and finally a protective case of a movable electronic device can be developed to have quakeproof and eye-catching effects.

The main objective of the invention is to improve the conventional protective case only having an effect of protecting backs of sides thereof but having no quakeproof effects and difficulty being found in a dark room so as to achieve quakeproof and eye-catching effects.

In order to achieve the above objective, a protective case of a movable electronic device is proposed to include a protective device enclosing the movable electronic device, wherein the movable electronic device comprises a smart phone or a tablet personal computer, wherein the protective device comprises a fluorescent portion easily recognized at night, wherein the protective device comprises a rubber quakeproof buffer portion at an inner side thereof, wherein the protective device comprises a side frame fitting a side of the movable electronic device, a top cover corresponding to a top side of the movable electronic device and joining the side frame, and a bottom cover corresponding to a bottom side of the movable electronic device and joining the side frame, wherein the side frame comprises joining portions corresponding to the top and bottom covers respectively, wherein the side frame is provided with an operating hole, wherein the top cover is provided with a screen portion and at least a through hole, wherein the bottom cover is provided with an image capture hole and a graphic display region, wherein the top and bottom covers, side frame and quakeproof buffer portion are tightly fitted such that complete protection, a quakeproof effect and an eye-catching effect at night can be achieved.

The accompanying drawings are included to provide a further understanding of the invention, and are incorporated as a part of this specification. The drawings illustrate embodiments of the invention and, together with the description, serve to explain the principles of the invention.

### BRIEF DESCRIPTION OF THE DRAWINGS

The drawings disclose illustrative embodiments of the present disclosure. They do not set forth all embodiments. Other embodiments may be used in addition or instead. Details that may be apparent or unnecessary may be omitted to save space or for more effective illustration. Conversely, some embodiments may be practiced without all of the details that are disclosed. When the same numeral appears in different drawings, it refers to the same or like components or steps.

Aspects of the disclosure may be more fully understood from the following description when read together with the accompanying drawings, which are to be regarded as illustrative in nature, and not as limiting. The drawings are not necessarily to scale, emphasis instead being placed on the principles of the disclosure.

FIG. 1 is a 3D assembly view in accordance with an embodiment of the present invention.

FIG. 2 is a schematically breakdown drawing in accordance with an embodiment of the present invention.

FIG. 3 is a view in accordance with an illumination embodiment of the present invention.

FIG. 4 is a view in accordance with a quakeproof embodiment of the present invention.

FIG. 4A is an enlarged view in accordance with a quakeproof embodiment of the present invention.

While certain embodiments are depicted in the drawings, one skilled in the art will appreciate that the embodiments depicted are illustrative and that variations of those shown, as well as other embodiments described herein, may be envisioned and practiced within the scope of the present disclosure.

### DETAILED DESCRIPTION OF THE INVENTION

Illustrative embodiments are now described. Other embodiments may be used in addition or instead. Details that may be apparent or unnecessary may be omitted to save space or for a more effective presentation. Conversely, some embodiments may be practiced without all of the details that are disclosed.

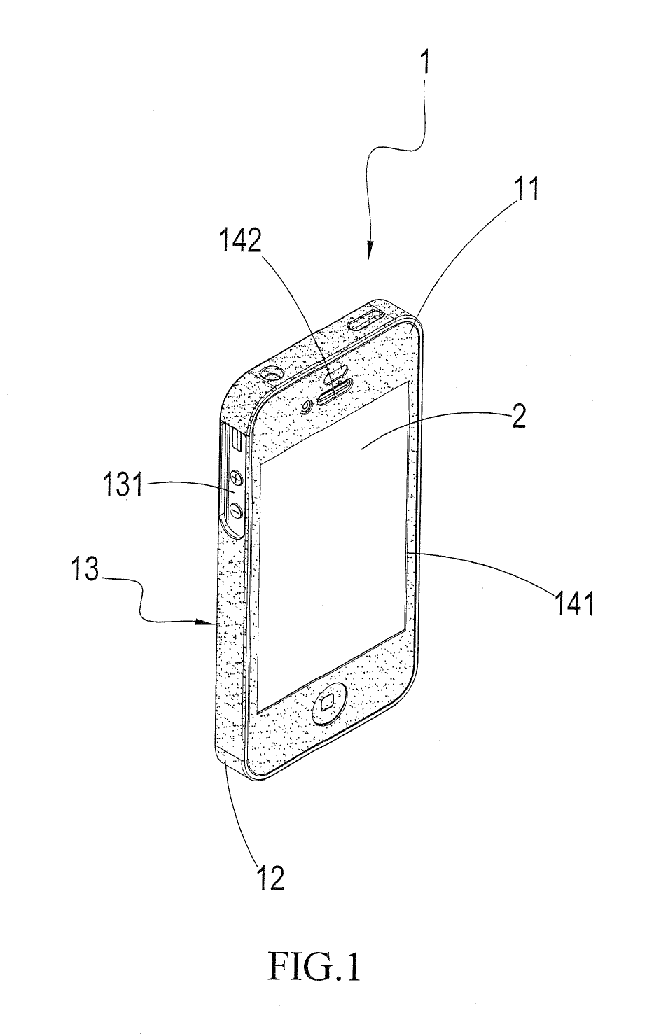

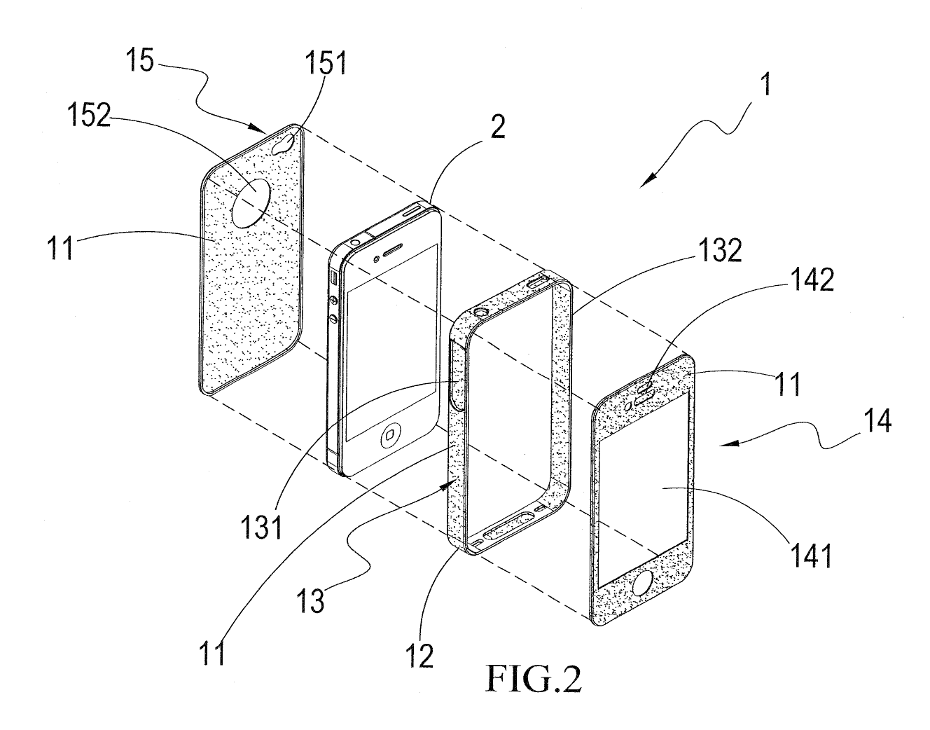

FIGS. 1 and 2 are a 3D assembly view and a schematically breakdown drawing in accordance with an embodiment of the present invention. Referring to FIGS. 1 and 2, a protective case of a movable electronic device 2 includes a protective device 1 enclosing the movable electronic device 2, wherein the movable electronic device 2 can be a smart phone or a tablet personal computer, wherein the protective device 1 comprises a fluorescent portion 11 easily recognized at night, wherein the protective device 1 comprises a rubber quakeproof buffer portion 12 at an inner side thereof, wherein the protective device 1 comprises a side frame 13 fitting a side of the movable electronic device 2, a top cover 14 corresponding to a top side of the movable electronic device 2 and joining the side frame 13, and a bottom cover 15 corresponding to a bottom side of the movable electronic device 2 and joining the side frame 13, wherein the side frame 13 comprises joining portions 132 corresponding to the top and bottom covers 14 and 15 respectively, wherein the side frame 13 is provided with an operating hole 131, wherein the top cover 14 is provided with a screen portion 141 and at least a through hole 142, wherein the bottom cover 15 is provided with an image capture hole 151 and a graphic display region 152.

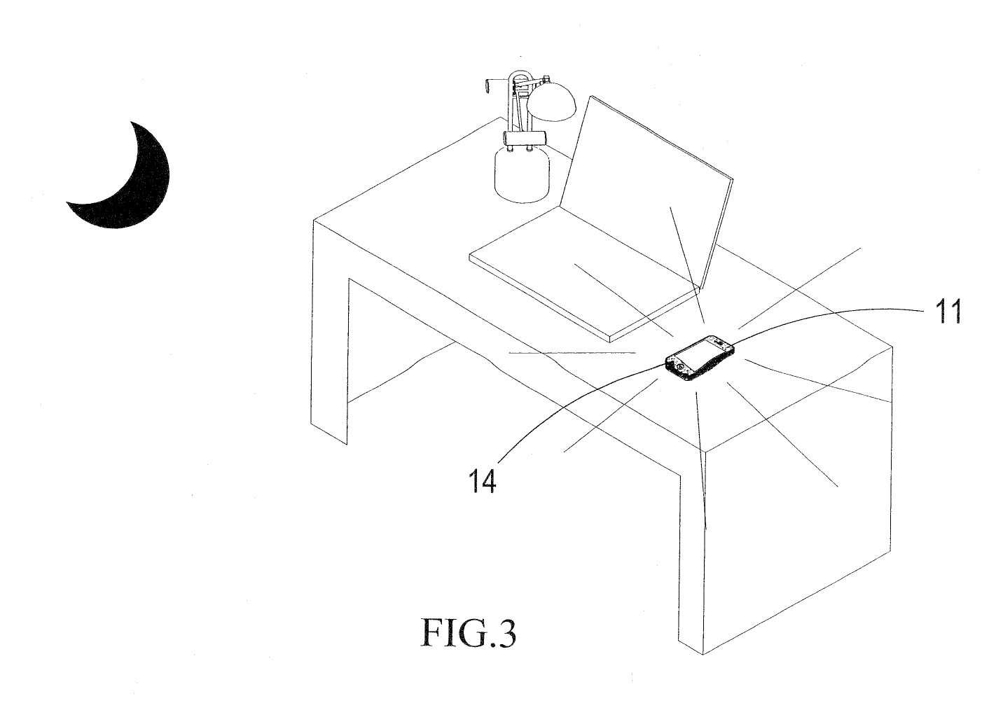

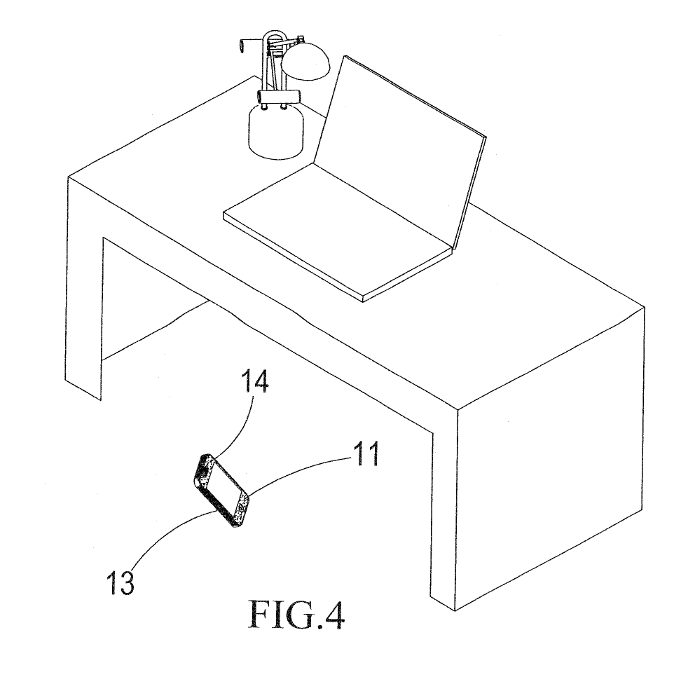

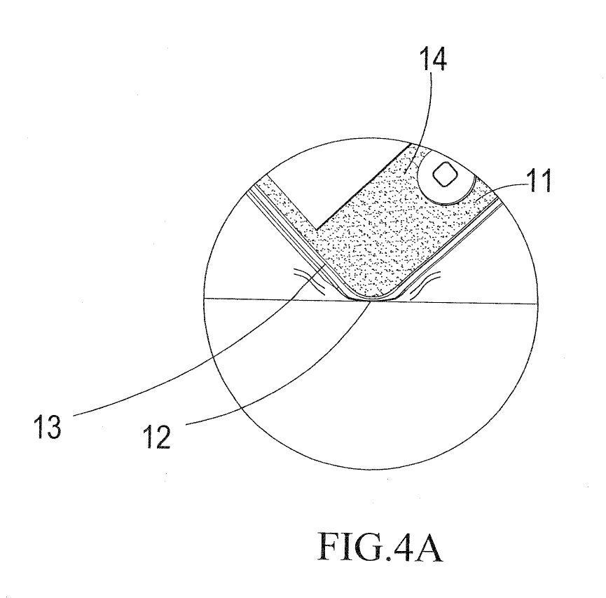

In accordance with the present invention, the above structure operates as below. FIG. 2 is a schematically breakdown drawing in accordance with an embodiment of the present invention. FIG. 3 is a view in accordance with an illumination embodiment of the present invention. FIG. 4 is a view in accordance with a quakeproof embodiment of the present invention. FIG. 4A is an enlarged view in accordance with a quakeproof embodiment of the present invention. Referring to FIGS. 2, 3, 4 and 4A, the fluorescent portion 11 can be arranged at any place of the side frame 13, top cover 14 or bottom cover 15 and can provide an eye-catching effect at night. Thus, the mobile electronic device 2 has a position that can be easily recognized in a dark room. Besides, the fluorescent portion 11 has a decoration effect. The top and bottom covers 14 and 15 join the joining portions 132 of the side frame 13 and accompany tight fitting of the quakeproof buffer portion 12. Thereby, this achieves complete protection and quakeproof, scratch-resistant and dust-resistant effects. The operating hole 131, screen portion 141, image capture hole 151 and through hole 142 lead a user to operate the mobile electronic device 2 and the graphic display region 152 leads the mobile electronic device 2 to display. This results in the mobile electronic device 2 that is easy to be operated and attractive in appearance.

Accordingly, referring to all Figures, comparing with the prior art, the present invention has the following advantages:
1. The fluorescent portion 11 provides an eye-catching effect at night. Thus, the mobile electronic device 2 has a position that can be easily recognized in a dark room.
2. The fluorescent portion 11 has a decoration effect and is attractive in appearance.
3. The top and bottom covers 14 and 15 join the joining portions 132 of the side frame 13 and accompany tight fitting of the quakeproof buffer portion 12. Thereby, this achieves complete protection and quakeproof, scratch-resistant and dust-resistant effects.

Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain. Furthermore, unless stated otherwise, the numerical ranges provided are intended to be inclusive of the stated lower and upper values. Moreover, unless stated otherwise, all material selections and numerical values are representative of preferred embodiments and other ranges and/or materials may be used.

The scope of protection is limited solely by the claims, and such scope is intended and should be interpreted to be as broad as is consistent with the ordinary meaning of the language that is used in the claims when interpreted in light of this specification and the prosecution history that follows, and to encompass all structural and functional equivalents thereof.

What is claimed is:

1. A protective case of a movable electronic device, comprising:
a protective device enclosing the movable electronic device, wherein the protective device comprises a fluorescent portion and a quakeproof buffer portion at an inner side thereof.

2. The protective case of claim 1, wherein the quakeproof buffer portion comprises a rubber.

3. The protective case of claim 1, wherein the protective device comprises a side frame fitting a side of the movable electronic device, a top cover corresponding to a top side of the movable electronic device and joining the side frame, and a bottom cover corresponding to a bottom side of the movable electronic device and joining the side frame.

4. The protective case of claim 1, wherein the side frame comprises joining portions corresponding to the top and bottom covers respectively.

5. The protective case of claim 3, wherein the top cover is provided with a screen portion.

6. The protective case of claim 3, wherein the top cover is provided with at least a through hole.

7. The protective case of claim 3, wherein the bottom cover is provided with an image capture hole.

8. The protective case of claim 3, wherein the bottom cover is provided with a graphic display region.

9. The protective case of claim 3, wherein the side frame is provided with an operating hole.

10. The protective case of claim 1, wherein the movable electronic device comprises a smart phone or a tablet personal computer.
